(19) United States
(12) Patent Application Publication
(10) Pub. No.: US 2010/0271760 A1
(43) Pub. Date: Oct. 28, 2010

(54) MULTI-LAYER FILM AND ELECTRONIC DEVICE SHELL WITH SAME

(75) Inventors: CHAO-TSANG WEI, Tu-Cheng (TW); GA-LANE CHEN, Santa Clara, CA (US); WEI-CHENG LING, Tu-Cheng (TW); CHIA-YING WU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/543,596

(22) Filed: Aug. 19, 2009

(30) Foreign Application Priority Data
Apr. 25, 2009 (CN) 200910301839.8

(51) Int. Cl. B32B 27/06; H05K 5/00

(52) U.S. Cl. 361/679.01; 428/220

(57) ABSTRACT

An exemplary multi-layer film includes a top layer, a bottom layer and medium layer. The top layer is configured for reflecting part of incident light to be a first reflected light and allowing another part of the incident light to transmit therethrough. The bottom layer is capable of clinging to the substrate, and is configured for reflecting the transmitted light to be a second reflected light. The medium layer is sandwiched between the top layer and the bottom layer, and is configured for controlling a light path difference between the first reflected light and the second reflected light, such that the first and second reflected lights interfere with each other and provide the multi-layer film with a desired color appearance.

### CROSS-REFERENCE TO RELATED APPLICATIONS

This application is related to commonly-assigned co-pending applications entitled, “MULTI-LAYER FILM STRUCTURE WITH MEDIUM LAYER,” (Atty. Docket No. US24328), and “MULTI-LAYER FILM AND ELECTRONIC DEVICE SHELL HAVING SAME,” (Atty. Docket No. US24658). The above-identified applications are filed simultaneously with the present application. The disclosures of the above identified applications are incorporated herein by reference.

### BACKGROUND

1. Technical Field

The present invention relates to multi-layer films, and particularly, to a colored multi-layer film, and an electronic device shell coated with the multi-layer film.

2. Description of Related Art

Colored shells are widely used in electronic devices, such as mobile phones. Currently, the coloration of such shells is usually produced by painting. However, many paints are not environmentally friendly. For example, some paints or by-products thereof can be harmful to humans. Furthermore, many painted surfaces are not wear-resistant and are easily scratched.

What is needed, therefore, is a film and an electronic device shell coated with the film, which can overcome the above-described shortcomings.

### BRIEF DESCRIPTION OF THE DRAWINGS

Many aspects of the present multi-layer film and electronic device shell can be better understood with reference to the following drawings. The components in the drawings are not necessarily drawn to scale, the emphasis instead being placed upon clearly illustrating the principles of the present multi-layer film and electronic device shell. Moreover, in the drawings, all the views are schematic, and like reference numerals designate corresponding parts throughout the views.

FIG. 1 is a cross-sectional view of part of a multi-layer film formed on a substrate, in accordance with a first embodiment.

FIG. 2 is a cross-sectional view of an electronic device shell in accordance with a second embodiment, the electronic device shell including the multi-layer film of FIG. 1.

### DETAILED DESCRIPTION OF EMBODIMENTS

Various embodiments of the present multi-layer film and electronic device shell will now be described in detail below and with reference to the drawings. In this description, unless the context indicates otherwise, a reference to “light” includes a reference to a light beam or light beams.

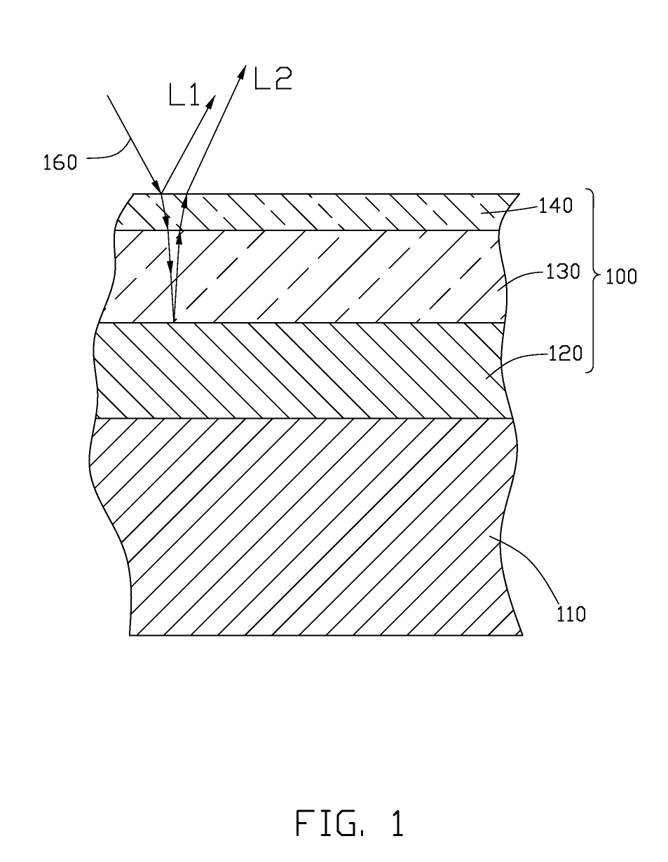

Referring to FIG. 1, an exemplary multi-layer film 100 in accordance with a first embodiment is shown. The multi-layer film 100 includes in sequence a bottom layer 120, a medium layer 130 and a top layer 140. The bottom layer 120 is configured to cling (adhere) to a substrate 110.

The top layer 140 and the bottom layer 120 are both metallic. The top layer 140 and the bottom layer 120 each can contain a material selected from a group consisting of aluminum, nickel, chromium, and alloy of the nickel and chromium. In the present embodiment, the top layer 140 and the bottom layer 120 contain different materials, and a reflection capability of the bottom layer 120 is greater than that of the top layer 140. Preferably, the top layer 140 is a reflective-transmissive layer, and the bottom layer 120 is a total-reflection layer. A thickness of the bottom layer 120 is greater than that of the top layer 140. In particular, a thickness of the top layer 140 can be in a range from 3 nanometers (nm) to 30 nm, and a thickness of the bottom layer 120 can be in a range from 5 nm to 200 nm.

The top layer 140 is capable of reflecting part of incident ambient light 160 (e.g., visible light which includes red, orange, yellow, green, blue, indigo and violet lightwaves) to be a first reflected light L1, and allowing another part of the incident ambient light 160 to transmit therethrough. The bottom layer 120 is capable of reflecting part of the transmitted light (not labeled) to be a second reflected light L2. The first reflected light L1 and the second reflected light L2 are fundamentally derived from the same incident ambient light 160 on the multi-layer film 100, and thus have the possibility of interfering with each other.

The medium layer 130 is sandwiched between the top layer 140 and the bottom layer 120. The medium layer 130 is transparent, and contains a material selected from a group consisting of silicon dioxide (SiO₂), titanium oxide (TiO₂), niobium pentoxide (Nb₂O₅), aluminum oxide (Al₂O₃), and magnesium fluoride (MgF₂). In certain embodiments, the medium layer 130 is made of the material selected from the group consisting of SiO₂, TiO₂, Nb₂O₅, Al₂O₃, and MgF₂. A thickness of the medium layer 130 can be in a range from 50 nm to 1000 nm. The thickness of the medium layer 130 impacts a light path difference between the first reflected light L1 and the second reflected light L2. With this configuration, the medium layer 130 is capable of controlling the light path difference between the first reflected light L1 and the second reflected light L2, such that the first reflected light L1 and the second reflected light L2 interfere with each other on the multi-layer film 100 to produce a desired color appearance of the multi-layer film 100.

When the light path difference between the first reflected light L1 and the second reflected light L2 is an even multiple of half of a central wavelength of a particular color lightwave of visible light, that color lightwave is enhanced. Under this condition, the multi-layer film 100 (and also the entire multi-layer film structure) appears to have a color substantially that of the most enhanced color lightwave. In one example, among the color lightwaves of visible light, i.e., red, orange, yellow, green, blue, indigo and violet, two of these color lightwaves may be enhanced. For instance, red and green lightwaves may both be enhanced. In such example, the multi-layer film 100 would appear to have a color comprised of a mixture of red and green; i.e., yellow. If the red lightwaves are enhanced more than the green lightwaves, the color has a tinge of red in it. If the green lightwaves are enhanced more than the red lightwaves, the color has a tinge of green in it.

In particular, when the medium layer 130 contains aluminum oxide, the relationship between the thickness of the medium layer 130 and the color appearance of the multi-layer 100 produced is generally as follows. When the thickness of the medium layer 130 is in a range from 195 nm to 215 nm, the color appearance of the multi-layer film 100 is substantially red. When the thickness of the medium layer 130 is in a range from 170 nm to 190 nm, the color appearance of the multi-layer film 100 is substantially orange. When the thickness of the medium layer 130 is in a range from 153 nm to 173 nm, the color appearance of the multi-layer film 100 is substantially yellow. When the thickness of the medium layer 130 is in a range from 448 nm to 468 nm, the color appearance of the multi-layer film 100 is substantially green. When the thickness of the medium layer 130 is in a range from 105 nm to 125 nm, the color appearance of the multi-layer film 100 is substantially blue. When the thickness of the medium layer 130 is in a range from 367 nm to 387 nm, the color appearance of the multi-layer film 100 is substantially violet.

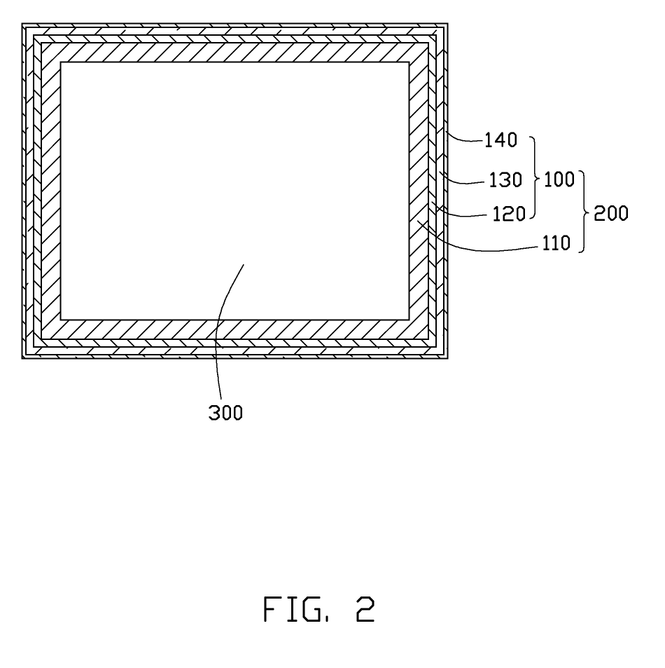

Referring to FIG. 2, a shell 200 of an electronic device 300 is provided as an exemplary embodiment of an application environment of the multi-layer film 100. The shell 200 includes an enclosure 110 configured as a substrate, and the multi-layer film 100 formed on an outer surface of the enclosure 110.

It is understood that the above-described embodiments are intended to illustrate rather than limit the disclosure. Variations may be made to the embodiments without departing from the spirit of the disclosure. Accordingly, it is appropriate that the appended claims be construed broadly and in a manner consistent with the scope of the disclosure.

What is claim is:

1. A multi-layer film for coating a substrate, the multi-layer film comprising:
a top layer configured for reflecting part of incident light to be a first reflected light and allowing another part of the incident light to transmit therethrough;
a bottom layer capable of clinging to the substrate, and configured for reflecting the transmitted light to be a second reflected light; and
a transparent medium layer sandwiched between the top layer and the bottom layer, and configured for controlling a light path difference between the first reflected light and the second reflected light such that the first and second reflected lights interfere with each other and provide the multi-layer film with a desired color appearance.

2. The multi-layer film as described in claim 1, wherein the top layer is a reflective-transmissive layer, and the bottom layer is a total-reflection layer.

3. The multi-layer film as described in claim 1, wherein the top layer and the bottom layer are both metallic, and a thickness of the bottom layer is greater than that of the top layer.

4. The multi-layer film as described in claim 3, wherein the top layer and the bottom layer each comprise material selected from the group consisting of aluminum, nickel, chromium, and alloy of nickel and chromium.

5. The multi-layer film as described in claim 4, wherein the top layer and the bottom layer comprise different materials, and a reflection capability of the bottom layer is greater than that of the top layer.

6. The multi-layer film as described in claim 1, wherein the medium layer comprises aluminum oxide.

7. The multi-layer film as described in claim 6, wherein a thickness of the medium layer is in a range from 195 nm to 215 nm, and the color appearance of the multi-layer film is substantially red.

8. The multi-layer film as described in claim 6, wherein a thickness of the medium layer is in a range from 170 nm to 190 nm, and the color appearance of the multi-layer film is substantially orange.

9. The multi-layer film as described in claim 6, wherein a thickness of the medium layer is in a range from 153 nm to 173 nm, and the color appearance of the multi-layer film is substantially yellow.

10. The multi-layer film as described in claim 6, wherein a thickness of the medium layer is in range from 448 nm to 468 nm, and the color appearance of the multi-layer film is substantially green.

11. The multi-layer film as described in claim 6, wherein a thickness of the medium layer is in range from 105 nm to 125 nm, and the color appearance of the multi-layer film is substantially blue.

12. The multi-layer film as described in claim 6, wherein a thickness of the medium layer is in range from 367 nm to 387 nm, and the color appearance of the multi-layer film is substantially violet.

13. A multi-layer film for coating a substrate, the multi-layer film comprising:
a reflective-transmissive layer configured for reflecting part of incident ambient light to be a first reflected light and transmitting another part of the incident ambient light therethrough;
a total-reflection layer capable of adhering to the substrate, and configured for reflecting the transmitted light to be a second reflected light; and
a transparent medium layer sandwiched between the reflective-transmissive layer and the total-reflection layer, wherein at least a thickness of the medium layer is configured for controlling a light path difference between the first reflected light and the second reflected light such that the first and second reflected lights interfere with each other and give the multi-layer film a predetermined color appearance.

14. The multi-layer film as described in claim 13, wherein reflective-transmissive layer and the total-reflection layer are both metallic.

15. The multi-layer film as described in claim 13, wherein the medium layer comprises material selected from the group consisting of silicon dioxide, titanium oxide, niobium pentoxide, aluminum oxide and magnesium fluoride.

16. The multi-layer film as described in claim 13, wherein a thickness of the medium layer is in a range from 50 nm to 1000 nm.

17. An electronic device shell, comprising:
an enclosure;
a bottom layer formed on the enclosure and a top layer formed over the bottom layer, the top layer configured for reflecting part of incident ambient light to be a first reflected light and transmitting another part of the incident ambient light therethrough, the bottom layer configured for reflecting the transmitted light to be a second reflected light; and
a transparent medium layer sandwiched between the top layer and the bottom layer, and configured for controlling a light path difference between the first reflected light and the second reflected light such that the first and second reflected lights interfere with each other and provide the electronic device shell with a desired color appearance.

18. The electronic device shell as described in claim 17, wherein the top layer is a reflective-transmissive layer, and the bottom layer is a total-reflection layer.
